(19) United States
(12) Patent Application Publication
(10) Pub. No.: US 2024/0407080 A1
(43) Pub. Date: Dec. 5, 2024

(54) PRINTED CIRCUIT BOARD WITH ENHANCED STRUCTURAL SUPPORT

(71) Applicant: Micron Technology, Inc., Boise, ID (US)

(72) Inventors: Quang Nguyen, Boise, ID (US); Koustav Sinha, Boise, ID (US); Christopher Glancey, Boise, ID (US)

(21) Appl. No.: 18/652,581

(22) Filed: May 1, 2024

Related U.S. Application Data
(60) Provisional application No. 63/471,125, filed on Jun. 5, 2023.

(51) Int. Cl. H05K 1/02; H05K 1/18; H05K 3/00

(52) U.S. Cl. CPC H05K 1/0271; H05K 3/0005; H05K 1/18; H05K 2201/068; H05K 2201/10159

(57) ABSTRACT

Systems, apparatuses, and methods related to a printed circuit board (PCB) with a plurality of layers are described. Embodiments of the present technology can include low coefficient of thermal expansion (CTE) strips, such as material with a CTE value of less than a threshold level, added into the core layer of the PCB. The added low CTE strips can lower the overall CTE mismatch between the PCB and the mounted components.

### CROSS-REFERENCE TO RELATED APPLICATION(S)

The present application claims priority to U.S. Provisional Patent Application No. 63/471,125, filed Jun. 5, 2023, the disclosure of which is incorporated herein by reference in its entirety.

### TECHNICAL FIELD

This disclosure relates generally to electronic devices, and more particularly, to electronic devices having circuit substrates with enhanced structural supports.

### BACKGROUND

Electronic components are mounted on a substrate, such as a printed circuit board (PCB), for an electronic device. During manufacturing, the components and the PCB may be heated and cooled, and the resulting temperature cycle can cause warpage in the overall mounted structure. For example, in surface mounting devices onto the PCB, solder joint connections are formed through melting, wetting, and solidification process. During this process, differences in the component and PCB thermal expansions can lead to warpage in the final assembly. Additionally, these differences in thermal expansion can introduce warpage and stress into the assembled PCB, solder joints, and components under component power cycling and environmental temperature cycling.

### BRIEF DESCRIPTION OF THE DRAWINGS

FIG. 1 illustrates a perspective view of a PCB with components, in accordance with one or more embodiments of the present technology.

FIGS. 2A and 2B illustrate a cross-sectional view of a PCB with low CTE strips in the core layer, in accordance with one or more embodiments of the present technology.

FIG. 3 illustrates a perspective view of a PCB with low CTE strips added in the longitudinal direction in the core layer, in accordance with one or more embodiments of the present technology.

FIG. 4 illustrates a detailed view of a portion of the PCB of FIG. 3 with low CTE strips added in the longitudinal direction in the core layer, in accordance with one or more embodiments of the present technology.

FIG. 5A illustrates a perspective view of a PCB core layer with low CTE strips extending along the transverse direction, in accordance with one or more embodiments of the present technology.

FIG. 5B illustrates a perspective view of a PCB core layer with low CTE strips extending along the longitudinal direction and the transverse direction, in accordance with one or more embodiments of the present technology.

FIG. 5C illustrates a perspective view of a PCB core layer with low CTE strips extending along the longitudinal direction with varying lengths, in accordance with one or more embodiments of the present technology.

FIG. 5D illustrates a perspective view of a PCB core layer with low CTE strips extending along the longitudinal direction and the transverse direction with varying lengths, in accordance with one or more embodiments of the present technology.

FIG. 5E illustrates a perspective view of a PCB core layer with low CTE strips added in freeform longitudinal and transverse directions at varying lengths, in accordance with one or more embodiments of the present technology.

FIG. 6 is a flow diagram illustrating an example method of designing a PCB with low CTE strips, in accordance with one or more embodiments of the present technology.

FIG. 7 is a schematic view of a system that includes an apparatus in accordance with embodiments of the present technology.

### DETAILED DESCRIPTION

An electronic device can include a substrate, such as a printed circuit board (PCB), that provides a structural support and electrical connections for electrical components (e.g., analog components, digital components, integrated circuits, or the like) mounted thereon. PCB warpage can occur during the component surface mount process, where solder joint connections are formed through melting, wetting, and solidification process. During this process, differences in the component and PCB thermal expansion can lead to warpage in the final assembly. Additionally, these differences in thermal expansion can introduce warpage and stress into the assembled PCB, solder joints, and components under component power cycling and environmental temperature cycling. When the PCBs have one lateral dimension greater than another lateral dimension, the mismatch can have greater impact along the longer lateral dimension and lead to corresponding structural deformations or warpages.

To reduce the warpage of the PCB, embodiments of the present technology can include low CTE strips (e.g., material with a CTE value of less than a threshold level, such as 5 parts per millimeter per degree Celsius (ppm/° C.)) added into the core layer of the PCB. The added low CTE strips can have one lateral dimension (e.g., a length along the longitudinal direction) that is greater (by, e.g., a factor of 1.5 or greater) than an orthogonal lateral dimension. Adding the low CTE strips can lower the overall CTE mismatch between the PCB and the components, thereby reducing the thermal induced warpage introduced during the reflow assembly process. Reducing the CTE mismatch between a PCB and the components improves reliability by reducing warpage and stress in the final assembly.

In some embodiments, the low CTE strips are added into the core layer of the PCB in the longitudinal and/or the traverse directions of the PCB. The position number, length, and width of the low CTE strips can vary based on the location of the components mounted on the PCB. As described in detail below, embodiments of the present technology can provide technical advantages over conventional technology and provide at least: 1) PCB warpage reduction; 2) no change in component design; 3) flexible treatment of PCB warpage; 4) solder joint reliability on the PCB; and 5) an improvement to the warpage due to the reflow assembly process and improved reliability due to the reduced thermal expansion mismatch between the components and the PCB after solder joints are formed.

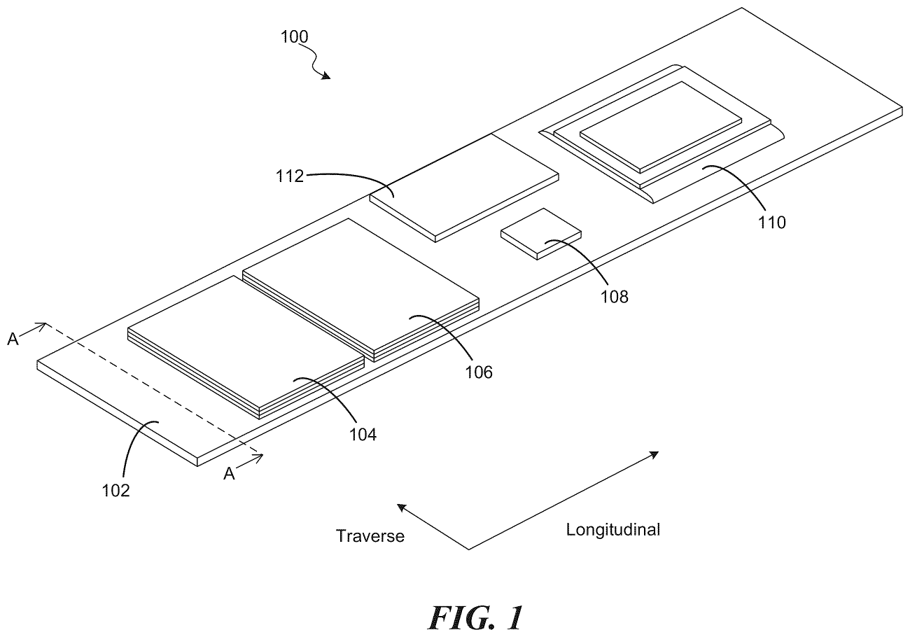

FIG. 1 illustrates a perspective view of electronic device 100 that includes a PCB 102 with mounted components 104, 106, 108, 110, and 112, in accordance with one or more embodiments of the present technology. The components 104, 106, 108, 110, and 112 (e.g., analog components, digital components, integrated circuits, or the like) can be mounted on the PCB 102. Some examples of the components may include, a central processing unit (CPU), a graphics processing unit (GPU), a memory (e.g., a Dynamic Random-Access Memory (DRAM)), a memory controller, a power management integrated circuit (PMIC), and the like.

The mounted components 104, 106, 108, 110, and 112 can generate heat during operation that causes warpage at various locations on the PCB 102. A factor causing warpage/deformations can be a mismatch in the CTE between the PCB 102 and the components 104, 106, 108, 110, and 112. Additionally, the different components can generate different amounts of heat and further provide different structural influences given their varied locations, sizes, and/or shapes. The combination of such factors can have greater impact along a longer lateral dimension in the longitudinal direction of PCB 102 than in a shorter lateral dimension in the traverse direction of the PCB 102. For example, a PCB with a dimension ratio greater than 3.6 of the longitudinal dimensions to the traverse dimensions has warpage during operation of the components. To reduce the warpage of the PCB 102, low CTE strips are added into the core layer of the PCB 102 to bring down the CTE of the PCB 102. The CTE strips lower the CTE mismatch effect between the PCB 102 and the components, thus reducing thermal induced warpage.

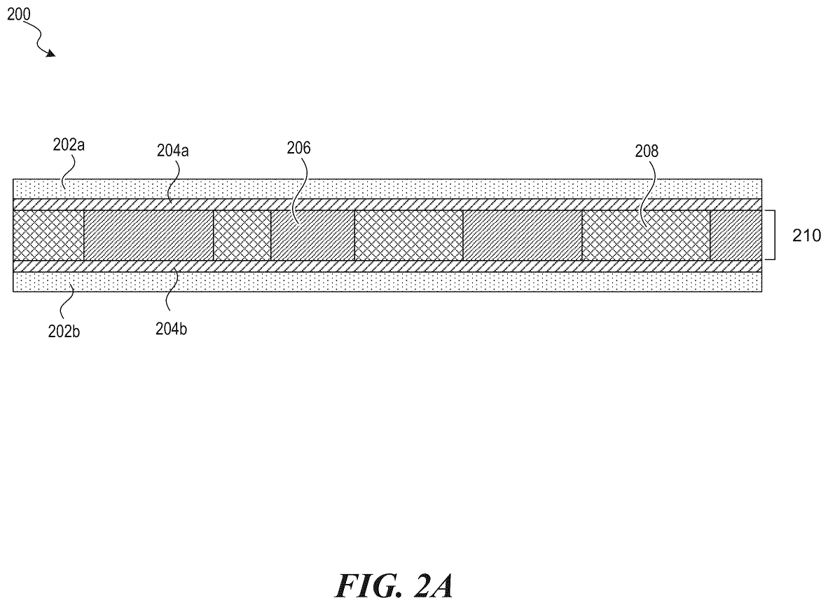

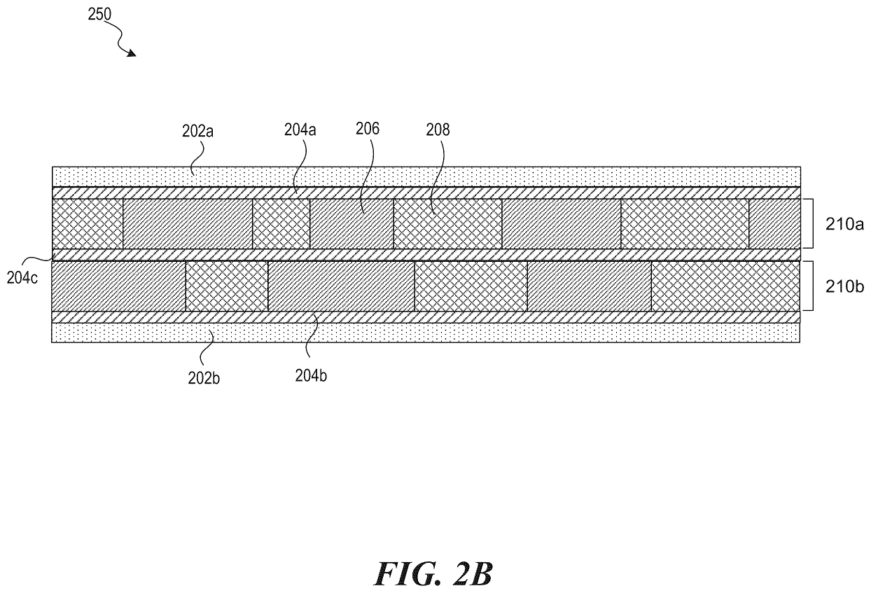

FIGS. 2A and 2B illustrate cross-sectional views taken along a dashed line A-A of FIG. 1. Example PCB 200 of FIG. 2A and PCB 250 of FIG. 2B (examples of the PCB 102 of FIG. 1) include low CTE strips 206 in the core layer 210, in accordance with one or more embodiments of the present technology. PCB 200 can include prepreg layers 202a and 202b on the exterior of the PCB 200 and metal layers 204a and 204b (e.g., copper material) that separate the prepreg layers 202 from the core layer 210. The low CTE strips 206 can be included in the core layer 210 between core material 208 (e.g., FR-4 material, glass, epoxy-resin based material, or the like). The position number, length, and width of the low CTE strips 206 can vary based on the location, the size, and/or shape of the components mounted on the PCB.

In some embodiments, the core layer 210 can include the core material 208 and the low CTE strips 206 arranged side-by-side or as a single layer along a lateral plane as illustrated in FIG. 2A. In other embodiments, such as illustrated in FIG. 2B, PCB 250 can include multiple core layers 210a and 210b. Metal layers 204a, 204b, and 204c can separate the prepreg layers 202 from the core layers 210. For example, the metal layers 204a, 204b, and/or 204c can be pressed over and under one or more layers, thereby affixing the components in the core layers 210a and 210b and preserving arrangements thereof.

The low CTE strips 206 can be placed in the core layers 210a and 210b between core material 208. Accordingly, one or more of the low CTE strips 206 in the layer 210a can overlap another CTE strip or instances of the core material 208 in the layer 210b. The multiple layers can be used to provide better control and/or gradients in an overall CTE at various locations in the PCB. Examples of materials for the low CTE strips 206 can include silicon with a CTE of 2.6 ppm/° C., ceramic with a CTE of 3-5 ppm/° C., material with a CTE in a range of 2.6-3.3 ppm/° C., or any material with a CTE value below 5 ppm/° C. In some embodiments, the low CTE strips 206 are added to the prepreg layers 202 in addition to or alternatively from the core layer 210.

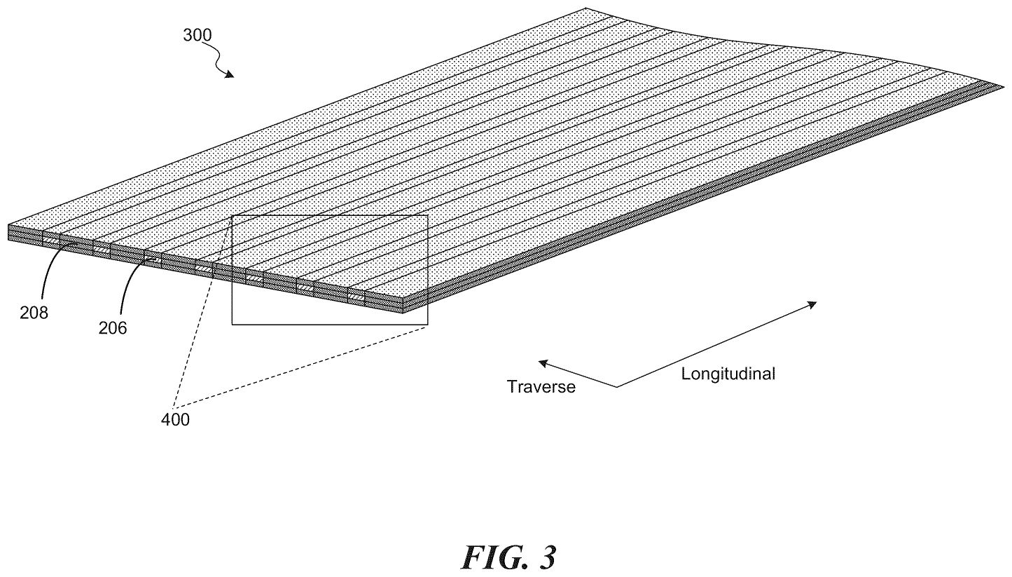

FIG. 3 illustrates a perspective view of a PCB 300 with low CTE strips added in the longitudinal direction on the core layer, in accordance with one or more embodiments of the present technology. The low CTE strips 206 are placed in the core layer in the longitudinal direction between the core material 208. The PCB 300 can have the low CTE strips extending the entire longitudinal length of the PCB 300. In some embodiments, the PCB 300 can have the low CTE strips 206 having a predetermined width and separated by a predetermined distance, such as for a standardized or shared-use design.

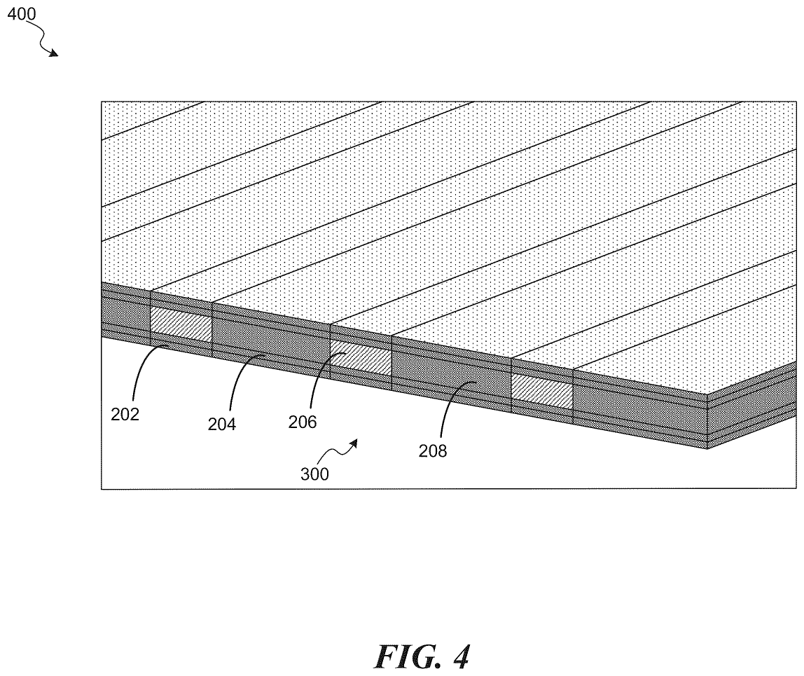

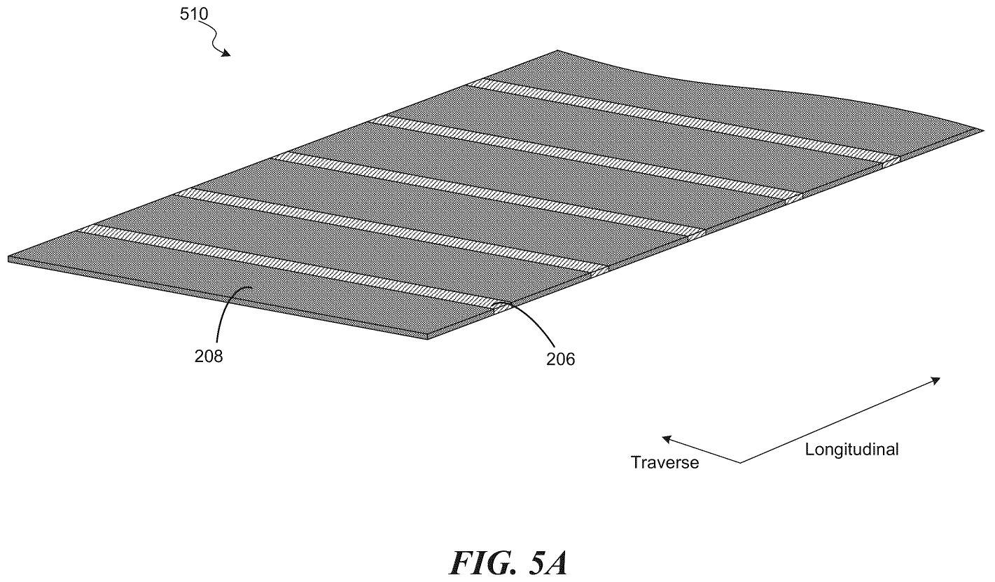

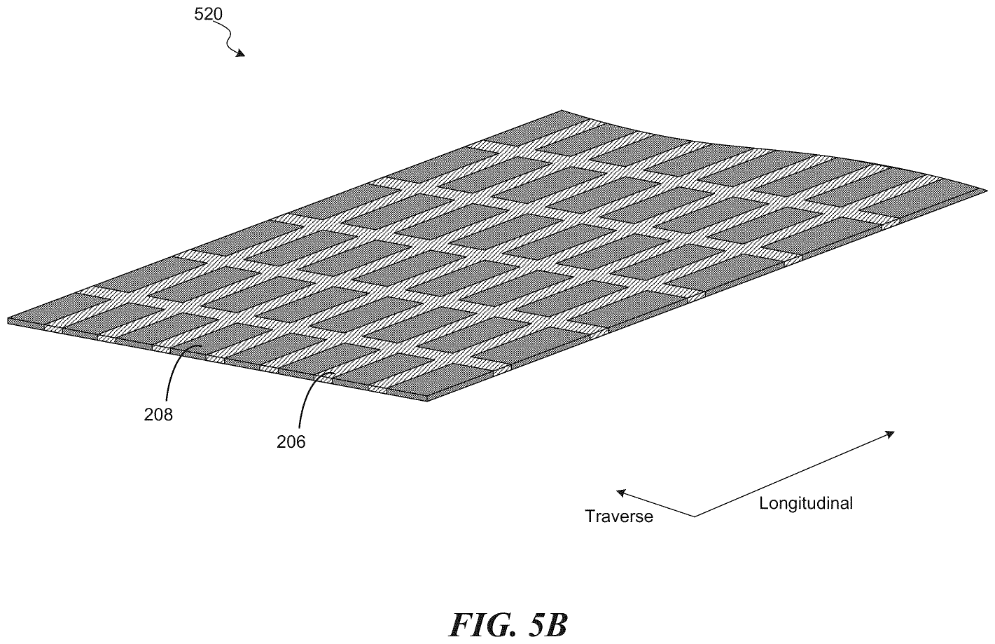

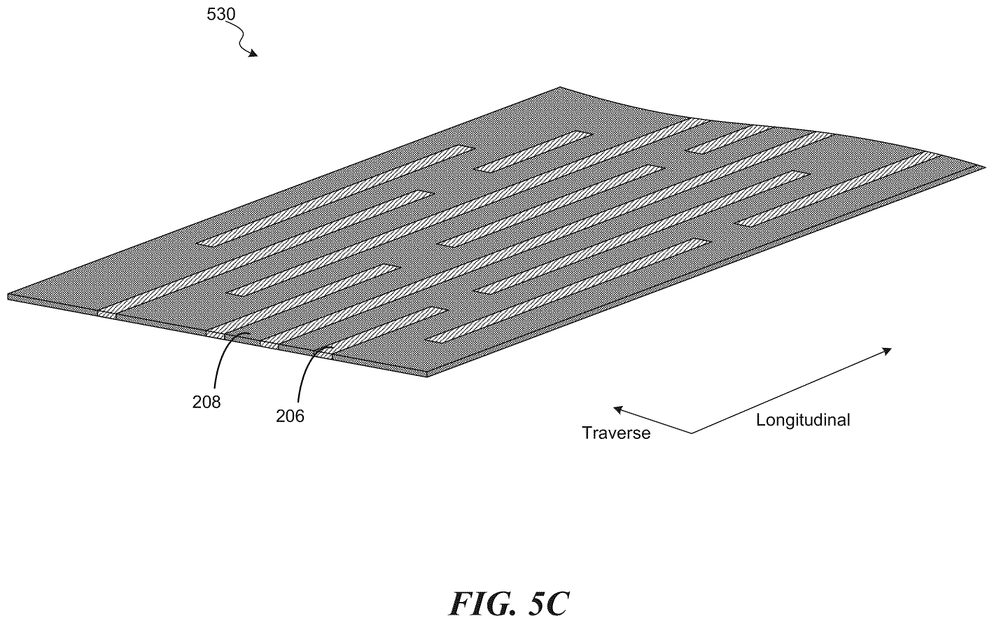

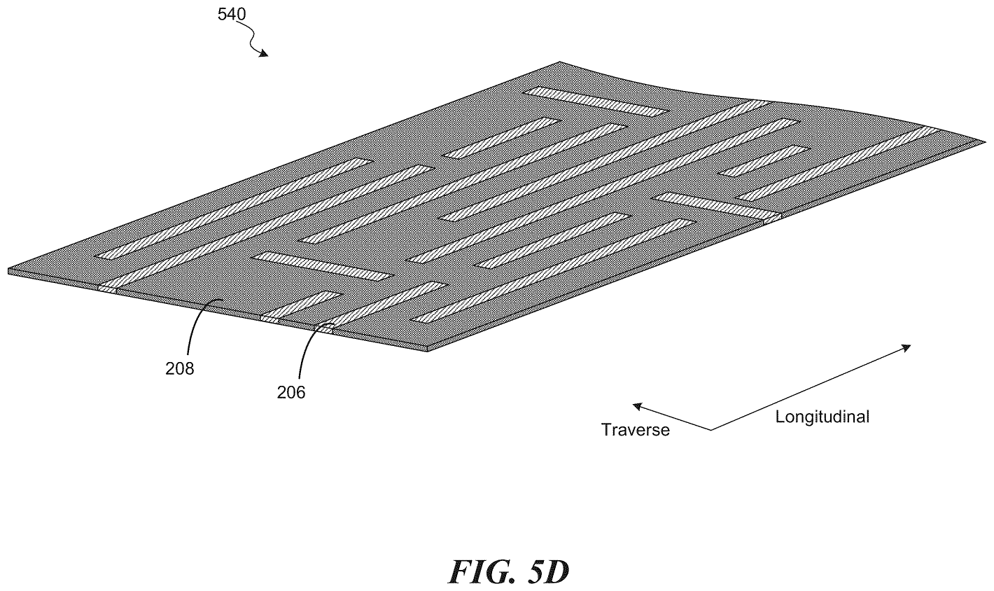

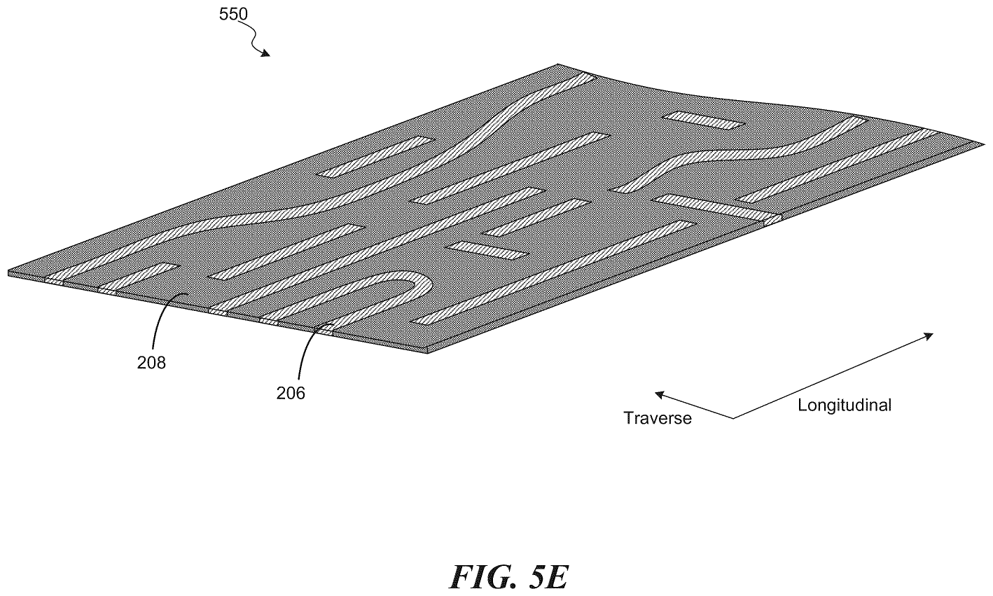

FIG. 4 illustrates a detailed view of a portion 400 of the PCB 300 of FIG. 3 with low CTE strips 206 added in the longitudinal direction in the core layer, in accordance with one or more embodiments of the present technology. PCB 300 can include prepreg layers 202 on the exterior of the PCB 300 and metal layers 204 that separate the prepreg layers 202 from the core layer. The low CTE strips 206 are placed in the core layer between core material 208. In some embodiments, the PCB can include one or more core layers that have the low CTE strips arranged differently. FIGS. 5A-5E illustrate some examples of such core layers.

FIG. 5A illustrates a perspective view of a PCB core layer 510 with low CTE strips 206 extending along the transverse direction, in accordance with one or more embodiments of the present technology. In some embodiments, the expected components and their locations can require the CTE reinforcement or adjustment along the traverse direction. To accommodate such designs, the PCB core layer 510 can include the low CTE strips 206 arranged to extend along the traverse direction, such as by having a width measured along a longitudinal direction that is significantly less (e.g., by a factor of 5 or more) than its length measured along the traverse direction.

FIG. 5B illustrates a perspective view of a PCB core layer 520 with low CTE strips 206 extending along the longitudinal direction and the transverse direction, in accordance with one or more embodiments of the present technology. The low CTE strips 206 can be placed in the core layer extending along the longitudinal direction and the transverse direction between core material 208. The low CTE strips 206 in the longitudinal direction can intersect with the low CTE strips 206 in the traverse direction.

FIG. 5C illustrates a perspective view of a PCB core layer 530 with low CTE strips 206 extending the longitudinal direction with varying lengths, in accordance with one or more embodiments of the present technology. The low CTE strips 206 can be placed in the core layer extending along the longitudinal direction with varying lengths between the core material 208. The low CTE strips 206 can span the entire longitudinal length of the PCB core layer 530 or any length of the PCB core layer 530. In some embodiments, the low CTE strips 206 span at least 50% of the longitudinal length of the PCB core layer 530.

FIG. 5D illustrates a perspective view of a PCB core layer 540 with low CTE strips 206 extending along the longitudinal direction and the transverse direction with varying lengths, in accordance with one or more embodiments of the present technology. The low CTE strips 206 can be placed in the core layer extending the longitudinal direction and transverse directions at varying lengths between the core material 208. The position, number, length, direction, and width of the low CTE strips 206 can vary based on the location and function of the components mounted on the PCB core layer 540.

FIG. 5E illustrates a perspective view of a PCB core layer 550 with low CTE strips 206 added in freeform longitudinal and transverse directions at varying lengths, in accordance with one or more embodiments of the present technology. The low CTE strips 206 can be placed in the core layer according to a customized shape and location between the core material 208. The number, length, direction, shape, and width of the low CTE strips 206 can vary based on the location and function of the components mounted on the PCB core layer 550.

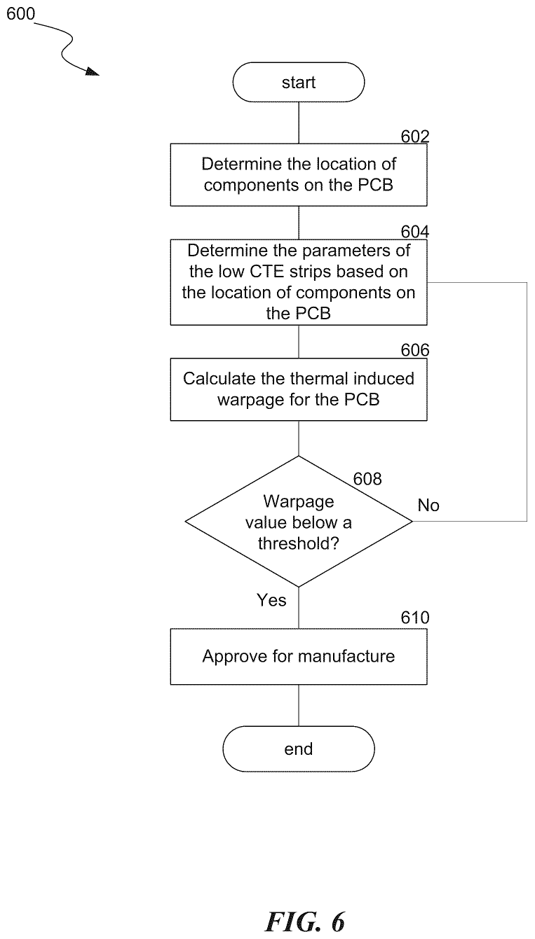

FIG. 6 is a flow diagram illustrating an example method 600 of designing a PCB with low CTE strips, in accordance with one or more embodiments of the present technology. The method 600 can determine the placement (e.g., size, shape, location, or the like) of low CTE strips (e.g., low CTE strips 206 of FIGS. 2A-5E) in a PCB, as described above.

At block 602, method 600 can include determining locations where components will be mounted on a PCB. The locations of the components can be determined based on the function of a component, heat displacement, footprint, wiring requirement, or any component placement design preferences or standards. The locations can be determined from coordinates assigned to each component that identify where on the PCB each component will be mounted. In other embodiments, the locations can be determined according to a circuit diagram or a requirement regarding the same provided by another party or entity, such as a circuit designer or a customer.

At block 604, method 600 can include determining the parameters (e.g., position, number, length, direction, and/or width) of the low CTE strips based on the location of components on the PCB. The low CTE strips can be placed under and/or around a footprint of the components to reduce the thermal warpage to the PCB caused by the operating components. Due to the hard properties of the low CTE strips, the components are generally attached over or closer to the core material (e.g., core material 208 of FIGS. 2A-5E) of the PCB instead of the low CTE strips.

Method 600 can include determining the parameters (e.g., locations and/or shapes) of the low CTE strips based on vias, sockets, receptacles, solder locations, holes, connectors, or any feature of the PCB in which a core material is preferred for mounting a component on the PCB. For example, the manufacturing system can generate a layout for the low CTE strips that avoids placing the low CTE strips at, under, overlapping, and/or within a threshold distance from vias on the PCB. The low CTE strips can be continuous or intermittent in the longitudinal direction and/or the traverse direction. The position, number, length, direction, and/or width of the low CTE strips can vary based on the location and/or function of the components to be mounted on the PCB and the connectors on the PCB. As illustrated in FIG. 5E, the low CTE strips can be various lengths, straight or freeform, and in various directions, based on the locations of mounted components on the PCB.

A machine learning or artificial intelligence (ML/AI) module may be configured to analyze component locations on a PCB and determine the parameters of low CTE strips to add to the core layer of the PCB to reduce thermal induced warpage. The ML/AI learning module may be configured to analyze the component locations and determine the parameters of the low CTE strips based on at least one ML/AI model trained on at least one dataset reflecting previous user determined parameters of low CTE strips based on component locations. The at least one ML/AI algorithm (and model) may be stored locally at databases and/or externally at databases (e.g., cloud databases and/or cloud servers). Client devices (e.g., personal computers, smart phones, tablets, etc.) may be equipped to access these ML/AI algorithms and intelligently determine parameters of low CTE strips in the core layer of a PCB based on at least one ML/AI model that is trained on historical low CTE strip parameters. For example, low CTE strip parameter history may be collected to train a ML/AI model to automatically determine the number, length, direction, and/or width of low CTE strips based on the locations of where components are mounted to a PCB.

As described herein, a ML/AI model may refer to a predictive or statistical utility or program that may be used to determine a probability distribution over one or more character sequences, classes, objects, result sets or events, and/or to predict a response value from one or more predictors. A model may be based on, or incorporate, one or more rule sets, machine learning, a neural network, or the like. In examples, the ML/AI models may be located on the client device, service device, a network appliance (e.g., a firewall, a router, etc.), or some combination thereof. The ML/AI models may process historical parameters of low CTE strip in PCBs and other data stores (e.g., PCB standards, etc.) to analyze the location of components to be mounted on a PCB and design the core layer of the PCB with inserted low CTE strips. Based on an aggregation of data from a PCB design database, external/internal portals, and other user data stores, at least one ML/AI model may be trained and subsequently deployed to automatically design PCBs with low CTE strips inserted in the core layer. The trained ML model may be deployed to one or more devices. As a specific example, an instance of a trained ML model may be deployed to a server device and to a client device. The ML model deployed to a server device may be configured to be used by the client device when, for example, the client device is connected to the internet. Conversely, the ML model deployed to a client device may be configured to be used by the client device when, for example, the client device is not connected to the internet. In some instances, a client device may not be connected to the internet but still configured to receive satellite signals with release assessment information. In such examples, the ML model may be locally cached by the client device.

At block 606, method 600 can include calculating (using, e.g., a computing system) the thermal induced warpage or CTE mismatch value for the PCB. The calculation can be based on simulation testing on the PCB design with the added low CTE strips to determine the thermal induced warpage or CTE mismatch value for the PCB. For example, by adding the low CTE strips in the longitudinal direction of the PCB, the CTE mismatch between the PCB and the mounted components can be reduced. The simulation results can show the predicted warpage improvement or the changes in the CTE mismatch by adding the low CTE strips in the core layer of the PCB.

At decision block 608, method 600 can include determining whether the thermal induced warpage or CTE mismatch value for the PCB is below a threshold (e.g., 230 μm of warpage or a corresponding estimate of the CTE mismatch). If the estimated warpage for the PCB is not below a predetermined acceptance threshold, method 600 can include adjusting the parameters of the CTE strips inserted in the core layer of the PCB as illustrated by the feedback loop to block 604. If the thermal induced warpage or CTE mismatch value for the PCB is below the threshold, at block 610, method 600 can include approving the PCB design for manufacture.

Based on the approval, the PCB design can be utilized to manufacture the PCB with low CTE strips in the core layer. For example, the PCB design can be provided to the PCB manufacturer. When manufacturing the PCB according to the approved design, the low CTE strips or material can be arranged with the core material according to the design. The arranged materials and strips can be pressed between or attached to holding structures (e.g., the metal layers 204 of FIGS. 2A and 2B). Additional structures, such as the prepreg layers 202 of FIG. 2A, signal routing structures/layers, vias, insulative layers, connections pads, solder resists, or other related structures, can be formed on the resulting/pressed core layer.

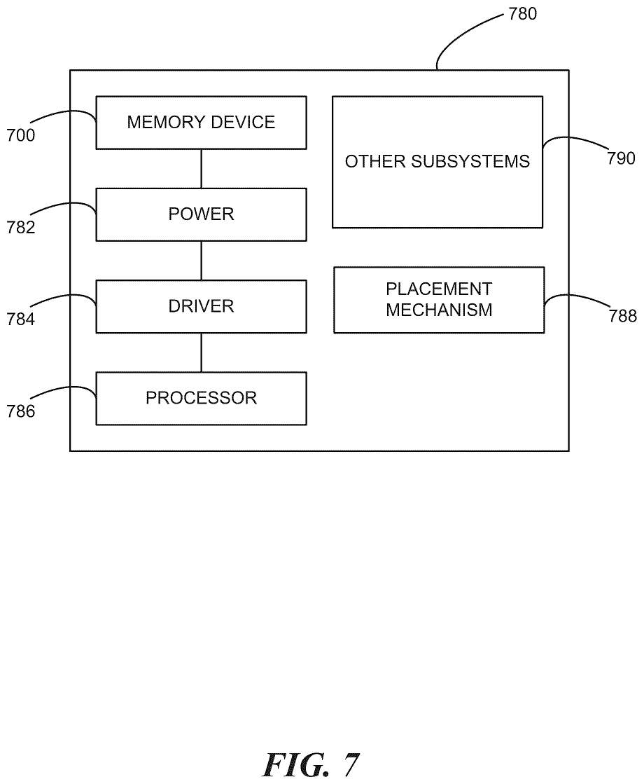

FIG. 7 is a schematic view of a system that includes an apparatus in accordance with embodiments of the present technology. Any one of the foregoing apparatuses (e.g., memory devices) associated with the PCBs described above with reference to FIGS. 1-6 can be incorporated into or implemented in memory (e.g., a memory device 700) or any of a myriad of larger and/or more complex systems, a representative example of which is system 780 shown schematically in FIG. 7. The system 780 can include the memory device 700, a power source 782, a driver 784, a processor 786, a placement mechanism 788, and/or other subsystems or components 790. The placement mechanism 788 can use ML/AI models to determine the position, number, length, direction, and width of the low CTE strips to add to the core layer of a PCB based on the location and function of the components mounted on the PCB (as described in FIG. 6).

The memory device 700 can include features generally similar to those of the apparatus described above with reference to FIGS. 1-6 and can therefore include various features for performing a direct read request from a host device. The resulting system 780 can perform any of a wide variety of functions, such as memory storage, data processing, and/or other suitable functions. Accordingly, representative systems 780 can include, without limitation, hand-held devices (e.g., mobile phones, tablets, digital readers, and digital audio players), computers, vehicles, appliances and other products. Components of the system 780 may be housed in a single unit or distributed over multiple, interconnected units (e.g., through a communications network). The components of the system 780 can also include remote devices and any of a wide variety of computer readable media.

From the foregoing, it will be appreciated that specific embodiments of the technology have been described herein for purposes of illustration, but that various modifications may be made without deviating from the technology. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the present technology and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structures includes information arranged as bits, words or code-words, blocks, files, input data, system generated data, such as calculated or generated data, and program data. Further, the term “dynamic” as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-7.

I/We claim:

1. An electronic device comprising:
a printed circuit board including a plurality of layers,
wherein the plurality of layers includes at least one metal layer, and at least one core layer,
wherein the at least one core layer includes core material and a coefficient of thermal expansion (CTE) adjustment structure extending along a first lateral direction and between the core material, and
wherein the CTE adjustment structure includes a material different from the core material and configured to reduce an overall CTE of the printed circuit board;
one or more components mounted on the printed circuit board.

2. The electronic device of claim 1, wherein the CTE adjustment structure has a CTE value below 5 ppm/° C., and wherein the plurality of layers includes at least one prepreg layer.

3. The electronic device of claim 1, wherein the CTE adjustment structure includes a first linear portion extending along the first lateral direction and a second linear portion extending along a second lateral direction of the printed circuit board, wherein a first dimension of the printed circuit board in the first lateral direction is greater than a second dimension of the printed circuit board in the second lateral direction.

4. The electronic device of claim 1, wherein:
the CTE adjustment structure is a first CTE adjustment structure; and
the printed circuit board includes in the at least one core layer a second CTE adjustment structure separate from the first CTE adjustment structure, wherein a combination of the first and second CTE adjustment structures are for having the overall CTE below a CTE threshold value.

5. The electronic device of claim 1, wherein the first lateral direction is a longitudinal direction of the printed circuit board.

6. The electronic device of claim 1, wherein a length of the CTE adjustment structure is at least half of a total length of the printed circuit board.

7. The electronic device of claim 1, wherein the CTE adjustment structure includes silicon or ceramic.

8. The electronic device of claim 1, wherein the CTE adjustment structure is located below the one or more components or adjacent to a footprint of the one or more components for reducing a mismatch or a difference in the overall CTE for the printed circuit board and the one or more components.

9. The electronic device of claim 8, wherein the CTE adjustment structure has a CTE value that is between a CTE value of the one or more components and a CTE value of the core material and/or closer to the CTE value of the one or more components than the CTE value of the core material.

10. The electronic device of claim 8, wherein:
the one or more components include a memory, a processor, or both;
at least a portion of the CTE adjustment structure located below or adjacent to the footprint of the memory, the processor, or both.

11. A printed circuit board comprising:
at least one metal layer; and
at least one core layer attached to the at least one metal layer and including (1) core material and (2) at least one coefficient of thermal expansion (CTE) adjustment structure extending along a first lateral direction and between the core material,
wherein the CTE adjustment structure includes a material different from the core material and configured to reduce an overall CTE of the printed circuit board, and
wherein a length, a width, a location, or a combination thereof of the CTE adjustment structure is based on one or more planned locations for mounting components on the printed circuit board.

12. The printed circuit board of claim 11, wherein at least a portion of the CTE adjustment structure is overlapped by or is within a predetermined distance from the one or more planned mounting locations, and wherein the printed circuit board includes at least one prepreg layer attached to the at least one metal layer.

13. The printed circuit board of claim 11, wherein the at least one core layer includes:
a first layer having the core material and the at least one CTE adjustment structure arranged coplanar with each other, wherein the core material comprises a first core material and the at least one CTE adjustment structure comprises a first CTE adjustment structure; and
a second layer having a second core material and a second CTE adjustment structure arranged coplanar to each other and over the first layer, wherein the second CTE adjustment structure overlaps the first core material, the first CTE adjustment structure, or both for providing a targeted CTE level at one or more overlapping portions.

14. The printed circuit board of claim 11, wherein the CTE adjustment structure includes silicon or ceramic for offsetting a CTE of the core material and produce the overall CTE to be closer to a CTE of silicon-based components.

15. A method for controlling a coefficient of thermal expansion (CTE) of a printed circuit board, the method comprising:
determining a set of dimensions for the printed circuit board; and
determining an arrangement of core material and one or more CTE adjustment structures in a core layer, wherein the one or more CTE adjustment structures is adjacent to and coplanar with the core material,
wherein the CTE adjustment structure includes material different from the core material and configured to reduce the CTE of the printed circuit board, and
wherein determining the arrangement includes deriving a shape, a set of dimensions, and a position for each of the one or more CTE adjustment structures according to a targeted CTE for the printed circuit board or portions thereof.

16. The method of claim 15, further comprising:
determining component locations on the printed circuit board, the component locations configured to receive one or more components, wherein the shape, the set of dimensions, and the position for each of the one or more CTE adjustment structures is derived based on the component locations.

17. The method of claim 16, wherein the shape, the set of dimensions, and the position for each of the one or more CTE adjustment structures are derived based on iteratively:
adjusting at least one of the shape, the set of dimensions, and the position;
calculating an estimated CTE or a corresponding warpage measure for the printed circuit board or a portion thereof; and
evaluating the estimated CTE based on a predetermined acceptance threshold.

18. The method of claim 16, wherein determining the arrangement includes:
identifying a location for a via associated with the determined component locations; and
locating the one or more CTE adjustment structures to avoid overlapping with the via location.

19. The method of claim 15, further comprising:
manufacturing the printed circuit board based on:
arranging the core material and the one or more CTE adjustment structures according to the determined arrangement;
attaching a metal layer to the core material and the one or more CTE adjustment structures; and
forming a prepreg layer over the metal layer.

20. The method of claim 15, wherein the shape, the set of dimensions, and the position for each of the one or more CTE adjustment structures is identified using a computing model configured to estimate a warpage measure associated with component locations and the arrangement based on at least one dataset representative of previous warpage results associated with previously determined shapes, dimensions, and positions CTE adjustment structures.
